(19) United States
(12) Patent Application Publication
(10) Pub. No.: US 2012/0320676 A1
(43) Pub. Date: Dec. 20, 2012

(54) SEMICONDUCTOR SYSTEM, NONVOLATILE MEMORY APPARATUS, AND AN ASSOCIATED READ METHOD

(75) Inventors: Sang Chul LEE, Icheon-si (KR); Jun Rye RHO, Icheon-si (KR); Sang Sik KIM, Icheon-si (KR)

(73) Assignee: HYNIX SEMICONDUCTOR INC., Icheon-si (KR)

(21) Appl. No.: 13/337,461

(22) Filed: Dec. 27, 2011

(30) Foreign Application Priority Data
Jun. 14, 2011 (KR) 10-2011-0057520

(51) Int. Cl. G11C 16/06; G11C 16/04

(52) U.S. Cl. 365/185.09; 365/185.18

(57) ABSTRACT

A semiconductor system includes a host configured to output a command, a control signal, an address signal, and data; and a nonvolatile memory apparatus configured to receive at least one of the command, the control signal, the address signal, and the data from the host, to provide a process result to the host, and to determine data levels of memory cells included in an overlap section of memory cell threshold voltage distributions based on an initial read bias voltage.

### CROSS-REFERENCES TO RELATED APPLICATION

The present application claims priority under 35 U.S.C. §119(a) to Korean application number 10-2011-0057520 filed on Jun. 14, 2011 in the Korean Intellectual Property Office, which is incorporated by reference in its entirety.

### BACKGROUND

1. Technical Field

The present invention relates to an electronic apparatus, and more particularly, to a semiconductor system, a nonvolatile memory apparatus, and an associated read method.

2. Related Art

The use of nonvolatile memory apparatuses such as flash memory has expanded into storage memory for portable information devices, a hard disk replacement of a semiconductor system, and so on.

A nonvolatile memory apparatus has developed from using a single level cell (SLC) for storing single-bit data in one memory cell to a multi-level cell (MLC) for storing multi-bit data. This has led to high integration of flash memory apparatus.

Each unit memory cell in a flash memory apparatus has a characteristic that is changed according to data retention ability, erase/write cycle, and influence of interference based on an arrangement pattern. As the use number of the flash memory apparatus increases, the characteristics of the memory cell may need to be changed.

FIG. 1 is a diagram explaining a read method depending on data distributions of memory cells in a nonvolatile memory apparatus. In the following descriptions, an SLC nonvolatile memory apparatus will be taken as an example.

Referring to FIG. 1, memory cells of the nonvolatile memory apparatus may be programmed to data Data1 or data Data2. In order to determine the levels of data stored in memory cells accessed for a read operation, a read bias voltage V_RD is applied. When memory cell have a threshold voltage higher than the read bias voltage V_RD, the memory cells are determined to be memory cells storing the data Data2, and when memory cell have a threshold voltage lower than the read bias voltage V_RD, the memory cell are determined to be memory cells storing the data Data1.

As the use for the nonvolatile memory apparatus increases, the characteristics of the memory cells are inevitably changed. Therefore, although the first memory cells were programmed to have distributions as shown in FIG. 1, the threshold voltage distributions of the memory cells have changed.

FIG. 2 is a diagram explaining a state in which an error occurs according to the distribution change of the nonvolatile memory apparatus.

Nonvolatile memory cells, for example, flash memory cells have a characteristic where the cell distribution may move to the left side from the read bias voltage as the data retention ability decreases, and moves to the right side as the erase/write cycle is repeated. This is shown in the diagram of FIG. 2. Furthermore, the threshold voltages of the memory cells are changed by an inter-cell-interference (ICI) effect in which a cell is affected by neighboring cells depending on the arrangement position of the cell.

Referring to FIG. 2, it can be seen that the threshold voltage distribution of the memory cells programmed into the data Data1 and the threshold voltage distribution of the memory cells programmed into the data Data2 are changed. When a first read bias voltage V_RD is applied in such a state where the threshold voltage distributions were changed, it is difficult to accurately determine the levels of the data. That is, it is difficult to discriminate whether the data levels of memory cells existing in a section A where the cell distributions overlap each other correspond to the data Data1 or the data Data2. Accordingly, a read operation cannot be performed with precision.

When an overlap section does not exist although the cell distributions are changed, a proper read bias voltage may be detected by a moving read method for increasing/decreasing the read bias voltage. As shown in FIG. 2, however, when the threshold voltage distributions of the memory cells programmed to different levels overlap each other, the moving read method cannot be applied.

Besides the moving read method, a log likelihood ratio (LLR) method may be used. The LLR method represents a probability for which level data stored in memory cells are to have, as a log scale. However, in order to use the LLR method, a cell distribution based on each data level should be expressed as a predetermined representative value for retention ability or at each erase/write cycle, but the shape is not constant. Therefore, even when the LLR method is applied, it is difficult to secure reliability of the read operation.

In order to implement high integration, a nonvolatile memory apparatus has developed into the MLC type. Therefore, as the number of data storable in one memory cell increases, a threshold voltage margin between the data gradually decreases. Furthermore, the incidence of error caused by the overlap of the threshold voltage distributions further increases.

### SUMMARY

In one embodiment of the present invention, a semiconductor system includes a host configured to output a command, a control signal, an address signal, and data, and a nonvolatile memory apparatus configured to receive at least one of the command, the control signal, the address signal, and the data from the host, to provide a process result to the host, and to determine data levels of memory cells included in an overlap section of memory cell threshold voltage distributions based on an initial read bias voltage.

In another embodiment of the present invention, a nonvolatile memory apparatus includes a memory area including a plurality of nonvolatile memory cells, and a controller configured to control the memory area and to determine data levels of memory cells included in a threshold voltage distribution overlap section according to threshold voltage distributions of the memory cells, in response to a read command.

In another embodiment of the present invention, a nonvolatile memory apparatus includes a memory area including a plurality of nonvolatile memory cells, and a controller configured to control the memory area. The controller includes, a reference table configured to store threshold voltage distribution information for each data level based on a use period of the memory cells and ICI weights calculated from an ICI ratio of the memory cells included in the memory area, and a level determination unit configured to determine data levels of memory cells in a threshold voltage distribution overlap section according to threshold voltage distributions of the memory cells using the reference table.

In another embodiment of the present invention, there is provided a read method for a nonvolatile memory apparatus including a level determination unit configured to determine data levels of nonvolatile memory cells. The read method includes deciding, by the level determination unit, an initial read bias voltage in response to a read command, detecting, by the level determination unit, an overlap section including the initial read bias voltage, and determining, by the level determination unit, data levels of memory cells existing in the overlap section.

### BRIEF DESCRIPTION OF THE DRAWINGS

Features, aspects, and embodiments are described in conjunction with the attached drawings:

FIG. 1 is a diagram explaining a read method depending on data distributions of memory cells in a nonvolatile memory apparatus;

FIG. 2 is a diagram explaining a state in which an error occurs according to distribution change of the nonvolatile memory apparatus;

FIG. 3 is a diagram explaining changes in threshold voltage of memory cells based on an ICI effect;

FIG. 4 is a configuration diagram of an exemplary semiconductor system according to one embodiment;

FIG. 5 is a configuration diagram of an exemplary controller of FIG. 4;

FIG. 6 is a configuration diagram of an exemplary level determination unit illustrated in FIG. 5;

FIG. 7 is a diagram explaining the level determination principle of an exemplary level determination unit; and

FIG. 8 is a flow chart showing an exemplary read method according to another embodiment.

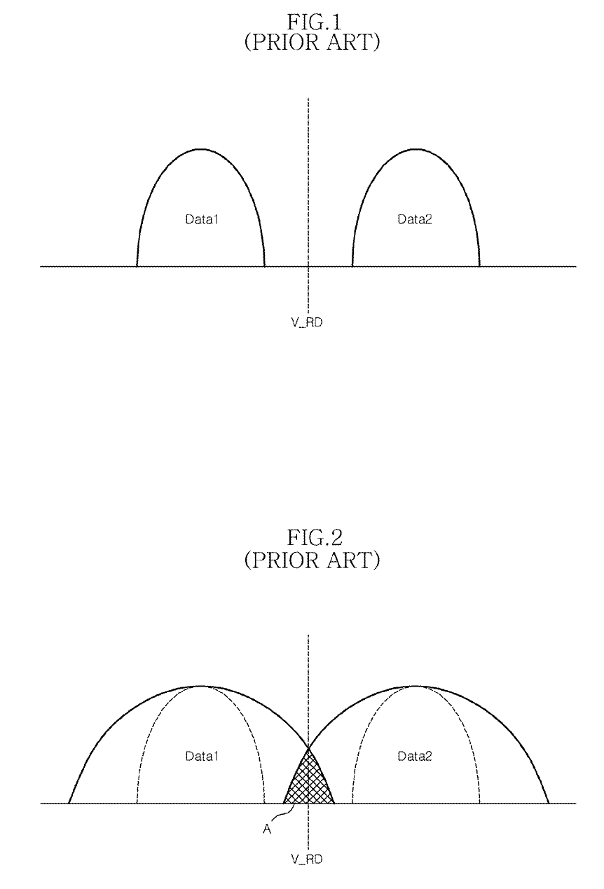

### DETAILED DESCRIPTION

A semiconductor system, a nonvolatile memory apparatus, and a read operation method according to the present invention will be described below with reference to the accompanying drawings through exemplary embodiments.

A nonvolatile memory cell such as, for example, a flash memory cell has a characteristic where the threshold voltage is changed by the ICI effect where the memory cell is influenced by surrounding memory cells depending on their arrangement.

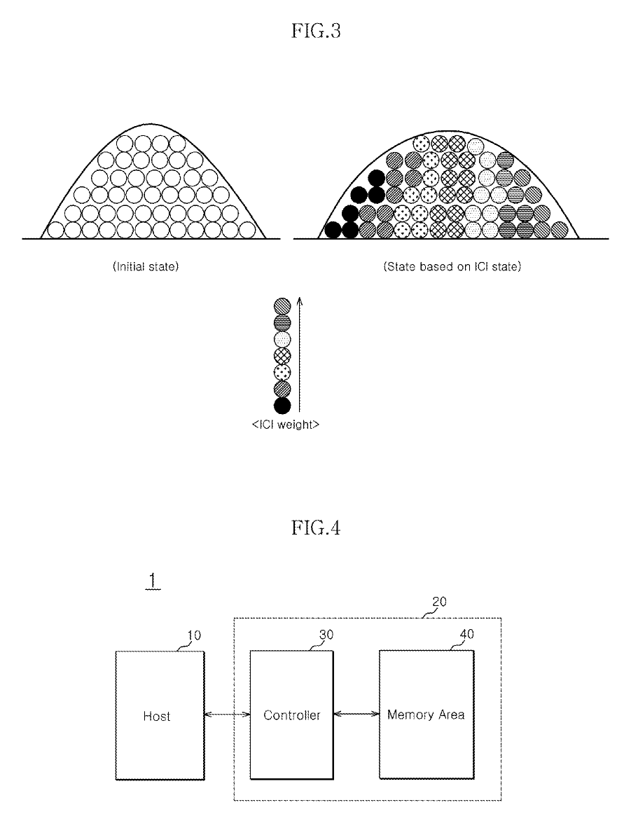

FIG. 3 is a diagram explaining changes in threshold voltage of memory cells based on the ICI effect.

A threshold voltage distribution of memory cells initially programmed to a specific data level is changed as the ICI effect is repeated. In particular, memory cells which are seriously affected by the ICI effect exhibit a characteristic where the threshold voltages increase.

Therefore, when threshold voltage distributions of memory cells programmed to different data levels overlap each other, memory cells whose threshold voltages were moved to the right side by the ICI effect, among cells existing in an overlapped section, may be found in case where the memory cells existing in the overlap section may be detected and an ICI effect falling on each memory cell may be checked. Furthermore, data programmed into the memory cells may be specified.

For this operation, a reference table may need to be constructed. The reference table stores threshold voltage distribution information based on the use period of memory cells, and an ICI effect based on the arrangement of each cell as a weight.

Therefore, the threshold voltage distribution information stored in the reference table may be used to figure out the overlap section, and the ICI weights of the use period of cells existing in the overlap section may be checked to determine data levels.

FIG. 4 is a configuration diagram of an exemplary semiconductor system according to one embodiment.

Referring to FIG. 4, the semiconductor system 1 includes a host 10 and a nonvolatile memory apparatus 20. The nonvolatile memory apparatus 20 includes a controller 30 and a memory area 40.

The host 10 is configured to transmit a command, a control signal, an address signal, data, and so on to the nonvolatile memory apparatus 20 and receive a process result based on the command from the nonvolatile memory apparatus 20.

The controller 30 of the nonvolatile memory apparatus 20 is configured to receive a command, a control signal, an address signal, data, and so on from the host 10 and control the memory area 40 in response to the signals. Furthermore, the controller 30 receives data outputted from the memory area 40 and provides the received data to the host 10.

The memory area 40 may be operated under control of the controller 30, and may include one or more flash memory chips, for example.

In this embodiment, when the use number of the memory area 40 or the like increases to change threshold voltage distributions of memory cells, the controller 30 uses the reference table to determine the data levels of memory cells existing in a section where the threshold voltage distributions overlap each other.

For this operation, the controller 30 decides an initial read bias voltage according to the number of writable data. When the threshold voltage distributions of the memory cells overlap each other, the controller 30 checks the overlap section according to the threshold voltage distribution information stored in the reference table.

Furthermore, among memory cells existing in the overlap section, a memory cell having a high ICI weight, that is, a memory cell which is seriously affected by the ICI effect, is considered to have a lower threshold voltage than the initial read bias voltage according to the ICI weights of the reference table.

Furthermore, as the data level is determined in such a manner, the controller performs error correction through an error correction circuit such that a reliable read operation may be performed.

FIG. 5 is a configuration diagram of an exemplary controller of FIG. 4.

Referring to FIG. 5, the controller 30 includes a host interface 310, a memory interface 320, a micro control unit (MCU) 330, a memory controller 340, a level determination unit 350, and an error correction code (ECC) unit 360.

The host interface 310 is configured to transmit and receive a command, a control signal, an address signal, and a data signal to and from the host 10. An interface between the host interface 310 and the host 10 may include any one of serial advanced technology attachment (SATA), parallel advanced technology attachment (PATA), SCSI, Express Card, PCI-Express and so on.

The memory interface 320 is configured to transmit a command, a control signal, an address signal, and a data signal from the memory area 40 and receive a process result from the memory area 40.

The MCU 330 is configured to transmit and receive a command, a control signal, an address signal, and a data signal to and from the host interface 310 or control the memory controller 340.

The memory controller 340 is configured to select a designated memory element among nonvolatile memory elements included in the memory area 40 and provide an erase, read, or write command. In particular, when the memory area 40 includes a flash memory, the memory controller 340 may perform a function of address mapping or ware-leveling.

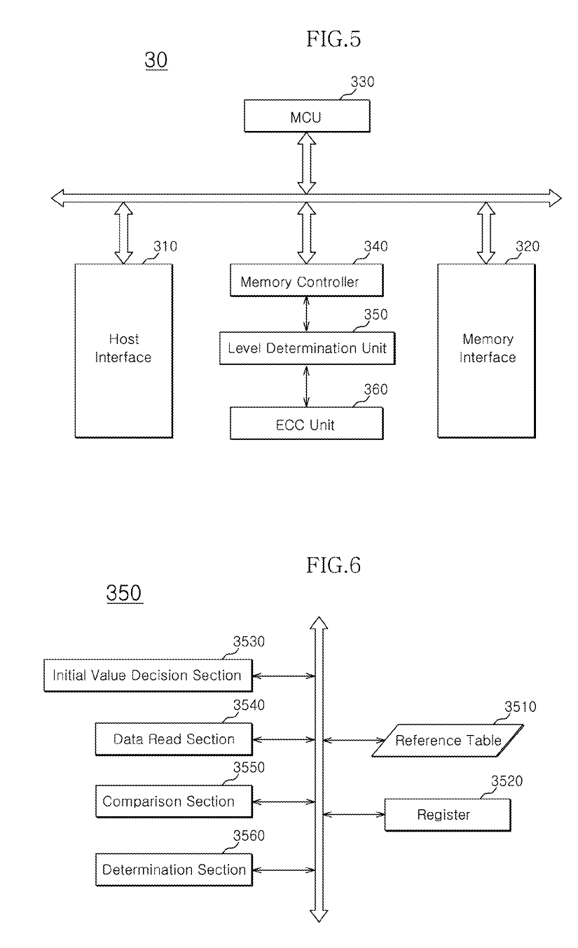

The level determination unit 350 includes the reference table with threshold voltage distribution information for each data level based on the use period of memory cells and the ICI weights of the respective memory cells. The level determination unit 350 is configured to set an initial read bias voltage in response to a read command, and check an overlap section where the threshold voltage distributions overlap each other and the ICI weights of memory cells existing in the overlap section, using the reference table. Furthermore, the level determination unit 350 determines the data levels of memory cells existing in the overlap section according to the checked ICI weights. The detailed operation of the level determination unit 350 will be described below with reference to FIG. 6.

The ECC unit 360 is configured to correct an error according to the data levels of the memory cells determined by the level determination unit 350.

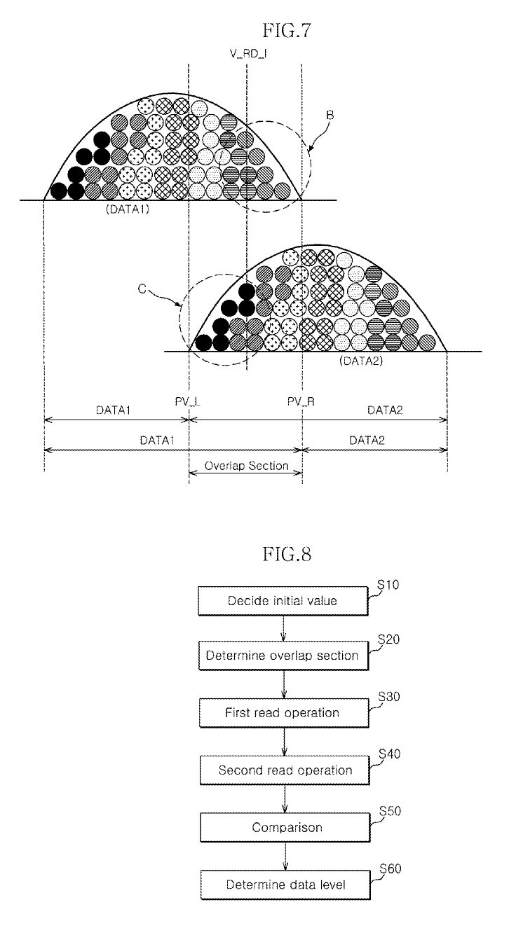

FIG. 6 is a configuration diagram of an exemplary level determination unit illustrated in FIG. 5. FIG. 7 is a diagram explaining the level determination principle of the level determination unit.

Referring to FIG. 6, the level determination unit 350 includes a reference table 3510, a register 3520, an initial value decision section 3530, a data read section 3540, a comparison section 3550, and a determination section 3560.

First, the reference table 3510 is configured to store the threshold voltage distribution information for each data level based on the use period of memory cells. The threshold voltage distribution information may be acquired by selecting a test process. Furthermore, the reference table 3510 stores the ICI weights calculated from the ICI ratio based on the arrangement of the memory cells.

The register 3520 temporarily stores data required for the operation of the level determination unit 350.

The initial value decision section 3530 is configured to decide an initial read bias voltage V_RD_I in response to a read command. The initial read bias voltage V_RD_I may be decided by a moving read method based on data counting. For example, the initial read bias voltage V_RD_I may be decided by counting memory cells by a value obtained by dividing the total number of memory cells by a storable bit number.

The data read section 3540 is configured to check the overlap section including the initial read bias voltage V_RD_I, using the threshold voltage distribution information stored in the reference table 3510. Referring to FIG. 7, the data read section 3540 acquires a left program voltage PV_L and a right program voltage PV_R based on the initial read bias voltage V_RD_I from the reference table 3510.

Furthermore, the data read section 3540 reads data stored in a memory cell using the left program voltage PV_L as a read bias voltage, and then stores the read data in the register 3520. Furthermore, the data read section 3540 reads data stored in a memory cell using the right program voltage PV_R as the read bias voltage, and then stores the read data in the register 3520.

The comparison section 3550 is configured to detect a memory cell of which the read result is changed, between the read result based on the left program voltage PV_L and the read result based on the right program voltage PV_R, by referring to the read results stored in the register 3520.

Referring to FIG. 7, when data are read based on the left program voltage PV_L, the data of memory cells having a lower threshold voltage than the left program voltage PV_L are read as data DATA1, and the data of memory cells having a higher threshold voltage than the right program voltage PV_L are read as data DATA2. Furthermore, when data are read based on the right program voltage PV_R, the data of memory cells having a lower threshold voltage than the right program voltage PV_R are read as data DATA1, and the data of memory cells having a higher threshold voltage than the right program voltage PV_R are read as data DATA2.

Therefore, the comparison section 3550 may detect memory cells which exist in the overlap section and of which the data are changed from the data DATA1 to the data DATA2.

The determination section 3560 checks the ICI weights of the respective memory cells detected by the comparison section 3550 from the reference table. Furthermore, the determination section 3560 determines a designated number of memory cells having a high ICI weight as memory cells having a lower threshold voltage than the initial read bias voltage V_RD_I.

Referring to FIG. 7, memory cells B having a high ICI weight and memory cells C having a low ICI weight coexist in the overlap section. That is, the memory cells B having a high ICI weight were initially programmed into the data DATA1, but the ICI ratio of the memory cells B is increased by the retention ability reduction, the erase/write cycle repetition, and the ICI effect such that the threshold voltages are increased. Therefore, a designated number of memory cells having a high ICI weight, which are stored in the reference table 3510 among the memory cells existing in the overlap section, may be specified as memory cells in which the data DATA1 are written.

When the data levels of the memory cells existing in the overlap section are determined by the determination section 3560, the ECC unit 360 performs an error correction process. Since the error correction operation of the ECC unit 360 deviates from the scope of the present invention, its detailed description is omitted.

FIG. 8 is a flow chart showing an exemplary read method according to another embodiment.

As a read command is provided, the initial value decision section 3530 decides an initial read bias voltage using a moving read method based on data counting, at S10. For example, when the number of memory cells is M and the number of storable bits is N, it may be assumed that M/N memory cells are programmed into a corresponding bit, in order to decide the initial read bias voltage.

When the initial read bias voltage is decided, the data read section 3540 detects left and right program voltages of the initial read bias voltage using the reference table 3510, and determines an overlap section through the left and right program voltages, at S20.

Then, the data read section 3540 reads data using the left program voltage as a read bias voltage and stores the read result in the register 3520 at S30 (first read operation). The data read section 3540 then reads data using the right program voltage as a read bias voltage and stores the read result in the register 3520 at S40 (second read operation).

Then, at S50, the comparison section 3550 detects memory cells whose data changed from the results of the first and second read operations. That is, the comparison section 3550 detects a memory cell existing in the overlap section.

When the memory cell existing in the overlap section is detected, the determination section 3560 determines the level of the memory cell existing in the overlap section using the ICI weight of the reference table 3510, at S60. At this time, a designated number of memory cells having a high ICI weight may be determined to be memory cells having a lower threshold voltage than the initial read bias voltage, but the present invention is not limited thereto.

In short, when the threshold voltage distributions of memory cells are changed so that the data of the memory cells cannot be read, the overlap section is searched based on the initial bias voltage. Furthermore, the data levels of the memory cells within the overlap section are decided according to the ICI weights of the memory cells included in the searched section.

For this operation, the reference table including the threshold voltage distribution information for each data level based on the use period of memory cells and the ICI weights calculated from the ICI ratio may be prepared. Furthermore, as a read command is provided, the data levels of the memory cells within the overlap section may be specified through the decision of the initial read bias voltage, the overlap section search, and the data level determination based on the ICI weights, and error correction is performed based on the data levels.

While certain embodiments have been described above, it will be understood to those skilled in the art that the embodiments described are by way of example only. Accordingly, the apparatus and method described herein should not be limited based on the described embodiments. Rather, the apparatus and method described herein should only be limited in light of the claims that follow when taken in conjunction with the above description and accompanying drawings.

What is claimed is:

1. A semiconductor system comprising:
a host configured to output a command, a control signal, an address signal, and data; and
a nonvolatile memory apparatus configured to receive at least one of the command, the control signal, the address signal, and the data from the host, to provide a process result to the host, and to determine data levels of memory cells included in an overlap section of memory cell threshold voltage distributions based on an initial read bias voltage.

2. The semiconductor system according to claim 1, wherein the nonvolatile memory apparatus comprises a controller and a memory area controlled by the controller, wherein the controller comprises:
a reference table configured to store threshold voltage distribution information for each data level based on a use period of memory cells included in the memory area and inter-cell-interference (ICI) weights calculated from an ICI ratio of the memory cells included in the memory area;
a level determination unit configured to decide the initial read bias voltage, to determine the overlap section based on the initial read bias voltage using the threshold voltage distribution information, and to determine the data levels of the memory cells included in the overlap section using the ICI weights; and
an error correction code (ECC) unit configured to correct an error according to the data levels of the memory cells determined by the level detector.

3. A nonvolatile memory apparatus comprising:
a memory area comprising a plurality of nonvolatile memory cells; and
a controller configured to control the memory area and to determine data levels of memory cells included in a threshold voltage distribution overlap section according to threshold voltage distributions of the memory cells.

4. The nonvolatile memory apparatus according to claim 3, wherein the controller comprises:
a reference table configured to store threshold voltage distribution information for each data level based on a use period of the memory cells included in the memory area and ICI weights calculated from an ICI ratio of the memory cells included in the memory area;
an initial value decision section configured to decide an initial read bias voltage;
a data read section configured to detect left and right program voltages of the threshold voltage distribution overlap section including the initial read bias voltage, using the reference table, and to provide a first read result obtained by using the left program voltage as a read bias voltage and a second read result obtained by using the right program voltage as the read bias voltage;
a comparison section configured to detect memory cells in which the first read result is different from the second read result; and
a determination section configured to determine data levels of the memory cells detected by the comparison section.

5. The nonvolatile memory apparatus according to claim 4, wherein the initial value decision section decides the initial read bias voltage such that when the number of bits stored in each of M memory cells is set to N, M/N memory cells are distributed at each data bit.

6. The nonvolatile memory apparatus according to claim 4, wherein the determination section determines a designated number of memory cells having a high ICI weight, among the memory cells detected by the comparison section, as memory cells having a lower threshold voltage than the initial read bias voltage, using the ICI weights of the reference table.

7. A nonvolatile memory apparatus comprising:
a memory area comprising a plurality of nonvolatile memory cells; and
a controller configured to control the memory area,
wherein the controller comprises:
a reference table configured to store threshold voltage distribution information for each data level based on a use period of the memory cells and ICI weights calculated from an ICI ratio of the memory cells included in the memory area; and
a level determination unit configured to determine data levels of memory cells in a threshold voltage distribution overlap section according to threshold voltage distributions of the memory cells using the reference table.

8. The nonvolatile memory apparatus according to claim 7, wherein the level determination unit comprises:
an initial value decision section configured to decide an initial read bias voltage;
a data read section configured to detect left and right program voltages of the threshold voltage distribution overlap section including the initial read bias voltage, using the reference table, and to provide a first read result obtained by using the left program voltage as a read bias voltage and a second read result obtained by using the right program voltage as the read bias voltage;
a comparison section configured to detect memory cells in which the first read result is different from the second read result; and
a determination section configured to determine data levels of the memory cells detected by the comparison section.

9. The nonvolatile memory apparatus according to claim 8, wherein the initial value decision section decides the initial read bias voltage such that when the number of bits stored in each of M memory cells is set to N, M/N memory cells are distributed at each data bit.

10. The nonvolatile memory apparatus according to claim 8, wherein the determination section determines a designated number of memory cells having a high ICI weight, among the memory cells detected by the comparison section, as memory cells having a lower threshold voltage than the initial read bias voltage, using the ICI weights of the reference table.

11. The nonvolatile memory apparatus according to claim 7, further comprising an ECC unit configured to correct an error according to the data levels of the memory cells determined by the level determination unit.

12. A read method for a nonvolatile memory apparatus including a level determination unit configured to determine data levels of nonvolatile memory cells, the read method comprising:
deciding, by the level determination unit, an initial read bias voltage in response to a read command;
detecting, by the level determination unit, an overlap section including the initial read bias voltage; and
determining, by the level determination unit, data levels of memory cells existing in the overlap section.

13. The read method of claim 12, wherein, in deciding the initial read bias voltage, the initial read bias voltage is decided in such a manner that when the number of bits stored in each of M memory cells is set to N, M/N memory cells are distributed at each data bit.

14. The read method of claim 12, wherein the nonvolatile memory apparatus comprises a reference table configured to store threshold voltage distribution information for each data level based on the use period of the memory cells and ICI weights calculated from an ICI ratio of the memory cells, and
in detecting the overlap section, left and right program voltages of the threshold voltage distribution overlap section including the initial read bias voltage are detected by using threshold voltage distribution information of the reference table.

15. The read method of claim 14, wherein determining the data levels of the memory cells comprises:
performing, by the level determination unit, a first read operation using the left program voltage as a read bias voltage;
performing, by the level determination unit, a second read operation using the right program voltage as the read bias voltage;
comparing a result of the first read operation with a result of the second read operation and detecting memory cells in which the result of the first read operation is different from the result of the second read operation; and
determining data levels of the detected memory cells based on the ICI weights of the reference table.

16. The read method of claim 15, wherein in determining the data levels of the detected memory cells, a designated number of memory cells having a high ICI weight, among the detected memory cells, are determined as memory cells having a lower threshold voltage than the initial read bias voltage.

17. The read method of claim 12, further comprising correcting an error according to the determined data levels of the memory cells, after determining the data levels of the memory cells.
